(19) United States
(12) Patent Application Publication
(10) Pub. No.: US 2023/0314943 A1
(43) Pub. Date: Oct. 5, 2023

(54) CHEMICALLY AMPLIFIED RESIST COMPOSITION AND METHOD FOR MANUFACTURING RESIST FILM USING THE SAME

(71) Applicant: Merck Patent GmbH, Darmstadt (DE)

(72) Inventors: Rui ZHANG, Kakegawa-shi (JP); Hiroshi HITOKAWA, Kakegawa-shi (JP); Tomohide KATAYAMA, Kakegawa-shi (JP)

(21) Appl. No.: 18/022,762

(22) PCT Filed: Aug. 23, 2021
(86) PCT No.: PCT/EP2021/073215

§ 371 Date: Feb. 23, 2023

(30) Foreign Application Priority Data
Aug. 26, 2020 (JP) 2020-142595

(51) Int. Cl. G03F 7/039; G03F 7/004; G03F 7/32

(52) U.S. Cl. CPC G03F 7/0397; G03F 7/0048; G03F 7/0045; G03F 7/32

(57) ABSTRACT

To provide a chemically amplified resist composition capable of forming a resist pattern having high rectangularity. A chemically amplified resist composition comprising an alkali-soluble resin (A) having a certain structure and a cLogP of 2.76 to 3.35, a photoacid generator (B), and a solvent (C).

### BACKGROUND OF THE INVENTION

### Technical Field

The present invention relates to a chemically amplified resist composition to be used in manufacturing semiconductor devices, semiconductor integrated circuits, and the like, and a method for manufacturing a resist film using the same.

### Background Art

In a process of manufacturing devices such as semiconductor, fine processing by lithographic technique using a photoresist has generally been employed. The fine processing process comprises forming a thin photoresist layer on a semiconductor substrate such as a silicon wafer, covering the layer with a mask pattern corresponding to a desired device pattern, exposing the layer with actinic ray such as ultraviolet ray through the mask, developing the exposed layer to obtain a photoresist pattern, and etching the substrate using the resulting photoresist pattern as a protective film, thereby forming fine unevenness corresponding to the above-described pattern.

Making finer the resist pattern is required, and a resist composition that can achieve this is required. For example, there are studies on chemically amplified resist compositions for the purpose of obtaining a resist pattern having high resolution and a good shape (Patent Documents 1 and 2).

### PRIOR ART DOCUMENTS

### Patent Documents

[Patent document 1] JP 2010-250271 A
[Patent document 2] JP 2018-109701 A

### SUMMARY OF THE INVENTION

### Problems to be Solved by the Invention

The present inventors considered that there are one or more problems still need improvement in the chemically amplified resist composition and use thereof. These include, for example, the following: the solubility of the solute is insufficient; the resist pattern is tapered; a resist pattern of sufficiently rectangular cannot be obtained; film loss before and after development is large; sufficient resolution cannot be obtained; dry etching resistance of the resist pattern is insufficient; hardness of the resist film is insufficient; hardness of the resist pattern is insufficient; LWR is insufficient; sensitivity of the resist composition is insufficient; the composition receives environmental impact in the resist pattern manufacturing process; a resist pattern with a high aspect ratio cannot be formed; there are many cracks in the resist film; the number of defects is large; and storage stability is poor.

The present invention has been made based on the technical background as described above, and provides a chemically amplified resist composition and a method for manufacturing a resist film using the same.

### Means for Solving the Problems

The chemically amplified resist composition according to the present invention comprises an alkali-soluble resin (A), a photoacid generator (B) and a solvent (C),
wherein
cLogP of the alkali-soluble resin (A) is 2.76 to 3.35, and the alkali-soluble resin (A) comprises at least one of the following repeating units:

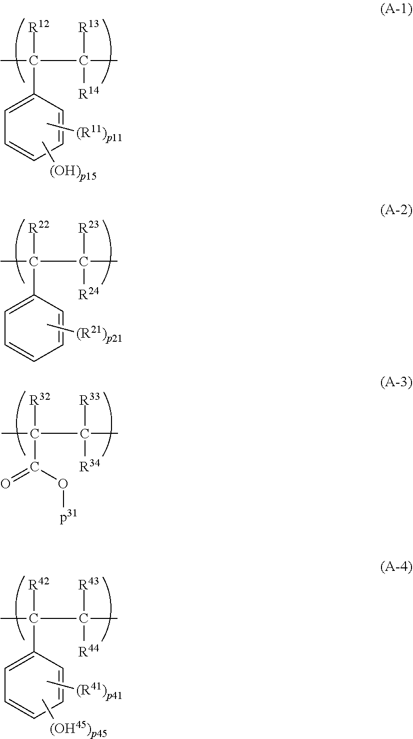

where
R¹¹, R²¹, R⁴¹ and R⁴⁵ are each independently C₁₋₅ alkyl (where —CH₂— in the alkyl can be replaced with —O—);
R¹², R¹³, R¹⁴, R²², R²³, R²⁴, R³², R³³, R³⁴, R⁴², R⁴³ and R⁴⁴ are each independently C₁₋₅ alkyl, C₁₋₅ alkoxy or —COON;
p11 is 0 to 4, p15 is 1 to 2, and p11+p15≤5;
p21 is 0 to 5;
p41 is 0 to 4, p45 is 1 to 2, and p41+p45≤5;
P³¹ is C₄₋₂₀ alkyl (where a part or all of the alkyl can form a ring, and a part or all of H in the alkyl can be replaced with halogen).

The method for manufacturing a resist film according to the present invention comprises the following steps:
(1) applying the above-described composition above a substrate; and
(2) heating the composition to form a resist film.

### Effects of the Invention

According to the present invention, one or more of the following effects can be desired.

Solubility of the solute is high. The resist pattern is not tapered. A resist pattern of rectangular can be obtained. The amount of film loss before and after development is small. Sufficient resolution can be obtained. Dry etching resistance of the resist pattern is high. Hardness of the resist film is high. Hardness of the resist pattern is high. LWR is sufficient. Sensitivity of the resist composition is sufficient. The composition does not receive environmental impact in the resist pattern manufacturing process. A resist pattern with a high aspect ratio can be formed. There are few cracks in the resist film. Number of defects is small. Storage stability is good.

### BRIEF DESCRIPTION OF THE DRAWINGS

FIG. 1 is a schematic illustration showing the cross-sectional view of a resist pattern.

### DETAILED DESCRIPTION OF THE INVENTION

### Mode for Carrying Out the Invention

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element. When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (C) or another component.

Hereinafter, embodiments of the present invention are described in detail.

### Chemically Amplified Resist Composition

The chemically amplified resist composition according to the present invention (hereinafter sometimes referred to as the composition) comprises an alkali-soluble resin (A) having a certain structure, a photoacid generator (B) and a solvent (C).

The composition according to the present invention is preferably a thin film chemically amplified resist composition.

Here, in the present invention, the thin film means a film having a thickness of less than 1 pm, and is preferably a film having a thickness of 50 to 900 nm (more preferably 50 to 500 nm). The viscosity of the composition according to the present invention is preferably 5 to 900 cP; more preferably 7 to 700 cP. Here, the viscosity is measured at 25° C. with a capillary viscometer.

The composition according to the present invention is, as a preferred embodiment, a thin film KrF chemically amplified resist composition. As another embodiment, the composition according to the present invention is preferably a thin film positive type chemically amplified resist composition; more preferably a thin film KrF positive type chemically amplified resist composition.

### Alkali-Soluble Resin (A)

The alkali-soluble resin (A) used in the present invention reacts with an acid to increase its solubility in an alkaline aqueous solution. Such polymer has, for example, an acid group protected by a protective group, and when an acid is added from outside, the protective group is eliminated and the solubility in an alkaline aqueous solution is increased. The alkali-soluble resin

(A) comprises at least one of the repeating units represented by the following (A-1), (A-2), (A-3) or (A-4).

The cLogP of the alkali-soluble resin (A) is 2.76 to 3.35; preferably 2.77 to 3.12; more preferably 2.78 to 3.00; further more preferably 2.78 to 2.99. Here, the cLogP is a value for calculating the common logarithm LogP of 1-octanol/water partition coefficient P. The cLogP can be calculated by the method described in “Prediction of Hydrophobic (Lipophilic) Properties of Small Organic Molecules” (Arup K. Ghose et al., J. Phys. Chem. A 1998, 102, 3762-3772). In the present specification, using ChemDraw Pro 12.0 of CambridgeSoft, the cLogP of each repeating unit is calculated and the cLogP×composition ratio of each repeating unit is summed up to calculate the cLogP of the alkali-soluble resin (A). When calculating the cLogP of each repeating unit, assuming that the polymerization is made per each repeating unit, and the calculation is performed without including the ends other than the repeating unit. For example, when the cLogP of repeating units A, B and C of the alkali-soluble resin (A) are respectively 2.88, 3.27 and 2.05, and the composition ratio is 6:2:2, the cLogP of the alkali-soluble resin (A) is 2.79.

Without wishing to be bound by theory, it is considered that the cLogP being within the above range brings about at least one of the above-mentioned effects. For example, it is expected that the control of solubility in the exposed region becomes accurate. This makes it possible to obtain an alkali-soluble resin having good properties from a large number of conceivable alkali-soluble resin.

The formula (A-1) is as follows:

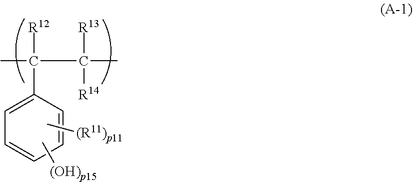

wherein
R¹¹ is each independently C₁₋₅ alkyl (where —CH₂— in the alkyl can be replaced with —O—);
R¹², R¹³ and R¹⁴ are each independently C₁₋₅ alkyl, C₁₋₅ alkoxy or —COON; and
p11 is 0 to 4, p15 is 1 to 2, and p11+p15≤5.

R¹¹ is preferably methyl or ethyl; more preferably methyl. R¹², R¹³ and R¹⁴ are preferably hydrogen or methyl; more preferably hydrogen.

The alkali-soluble resin (A) can contain a plurality of types of structural units represented by the formula (A-1). For example, it is possible for the resin to have a structural unit of p15=1 and a structural unit of p15=2 at a ratio of 1:1. In this case, it becomes that p15=1.5 as a whole. Hereinafter, unless otherwise specified, the same applies to the numbers for representing resin and polymer in the present invention.

p11 is preferably 0 or 1; more preferably 0.

p15 is preferably 0 or 1; more preferably 1.

An exemplified embodiment of the formula (A-1) includes the following:

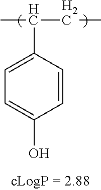

The formula (A-2) is as follows:

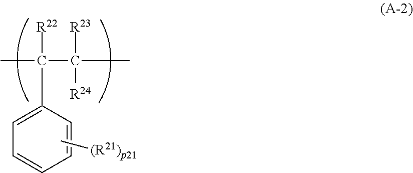

wherein
R²¹ is each independently C₁₋₅ alkyl (where —CH₂— in the alkyl can be replaced with —O—);
R²², R²³ and R²⁴ are each independently C₁₋₅ alkyl, C₁₋₅ alkoxy or —COON; and
p21 is 0 to 5.

R²¹ is preferably methyl, ethyl, t-butyl or t-butoxy; more preferably methyl or ethyl; more preferably methyl.

R²², R²³ and R²⁴ are preferably hydrogen or methyl; more preferably hydrogen.

p21 is preferably 0, 1, 2, 3, 4 or 5; more preferably 0 or 1; further preferably 0.

An exemplified embodiment of the formula (A-2) includes the following:

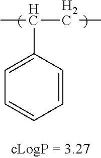

The formula (A-3) is as follows:

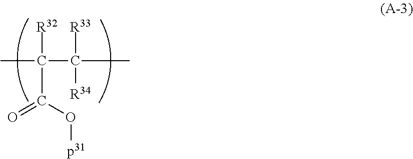

wherein
R³², R³³ and R³⁴ are each independently C₁₋₅ alkyl, C₁₋₅ alkoxy or —COOH; and
P³¹ is C₄₋₂₀ alkyl (where a part or all of the alkyl can form a ring, and a part or all of H in the alkyl can be replaced with halogen). The alkyl moiety of P³¹ is preferably branched or cyclic. When the C₄₋₂₀ alkyl in P³¹ is replaced with halogen, it is preferable that all are replaced, and the halogen that replaces is preferably F or Cl; more preferably F. It is a preferred embodiment of the present invention that H of the C₄₋₂₀ alkyl in P³¹ is not replaced with any halogen.

R³², R³³ and R³⁴ are preferably hydrogen, methyl, ethyl, t-butyl, methoxy, t-butoxy or —COOH; more preferably hydrogen or methyl; further preferably hydrogen.

P³¹ is preferably methyl, isopropyl, t-butyl, cyclopentyl, methylcyclopentyl, ethylcyclopentyl, cyclohexyl, methylcyclohexyl, ethylcyclohexyl, adamantyl, methyladamantyl or ethyladamantyl; more preferably t-butyl, ethylcyclopentyl, ethylcyclohexyl or ethyladamantyl; further preferably t-butyl, ethylcyclopentyl or ethyladamantyl; further more preferably t-butyl.

Exemplified embodiments of the formula (A-3) include the following:

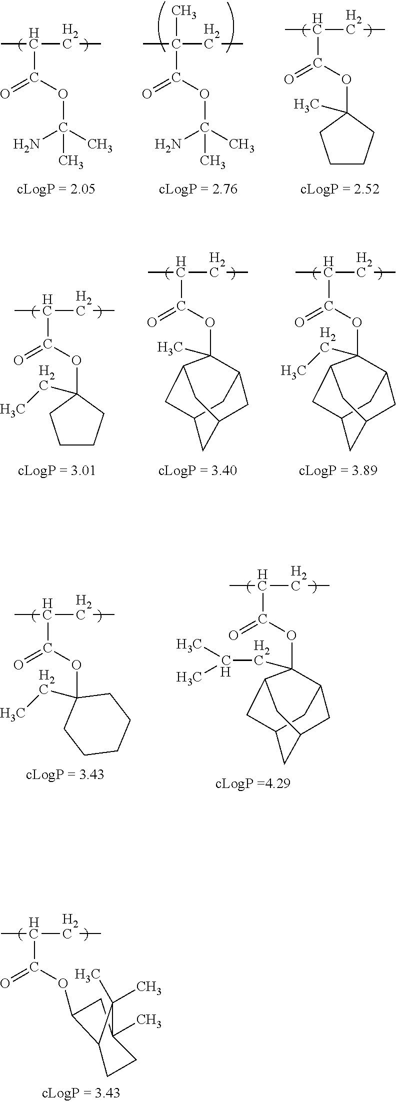

The formula (A-4) is as follows:

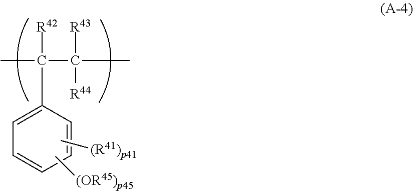

wherein
R⁴¹ and R⁴⁵ are each independently C₁₋₅ alkyl (where —CH₂— in the alkyl can be replaced with —O—);
R⁴², R⁴³ and R⁴⁴ are each independently C₁₋₅ alkyl, C₁₋₅ alkoxy or —COON; and
p41 is 0 to 4, p45 is 1 to 2, and p41+p45≤5.

R⁴⁵ is preferably methyl, t-butyl or —CH(CH₃)—O—CH₂CH₃.

R⁴¹ is preferably methyl, ethyl or t-butyl; more preferably methyl.

R⁴², R⁴³ and R⁴⁴ are preferably hydrogen or methyl; more preferably hydrogen.

p41 is preferably 0, 1, 2, 3 or 4; more preferably 0 or 1; further preferably 0.

p45 is preferably 1 or 2; more preferably 1.

Exemplified embodiments of the formula (A-4) include the following:

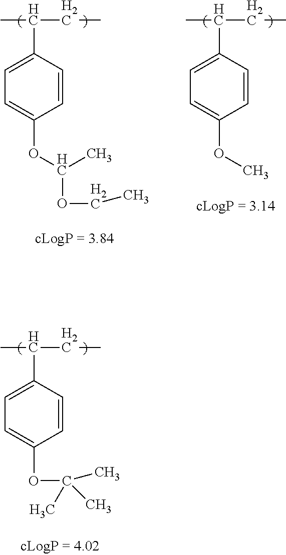

These structural units are appropriately compounded according to the purpose, and their compounding ratio is not particularly limited as long as cLogP satisfies 2.76 to 3.35. It is a preferable embodiment that the compounding is made so that the rate of increase in solubility in the alkaline aqueous solution becomes appropriate.

The numbers of repeating units n_{A-1}, n_{A-1}, n_{A-1} and n_{A-4} of the repeating units (A-1), (A-2), (A-3) and (A-4) in the alkali-soluble resin (A) are described below:

n_{A-1}/(n_{A-1}+n_{A-2}+n_{A-3}+n_{A-4}) is preferably 40 to 80%; more preferably 50 to 80%; further preferably 55 to 75%; further more preferably 60 to 70%.

n_{A-2}/(n_{A-1}+n_{A-2}+n_{A-3}+n_{A-4}) is preferably 0 to 40%; more preferably 5 to 35%; further preferably 5 to 25%; further more preferably 10 to 20%.

n_{A-3}/(n_{A-1}+n_{A-2}+n_{A-3}+n_{A-4}) is preferably 0 to 40%; more preferably 10-35%; further preferably 15 to 35%; further more preferably 20 to 30%.

n_{A-4}/(n_{A-1}+n_{A-2}+n_{A-3}+n_{A-4}) is preferably 0 to 40%; more preferably 10 to 35%; further preferably 15 to 35%; further more preferably 20 to 30%.

A preferred embodiment includes the following:

n_{A-1}/(n_{A-1}+n_{A-2}+n_{A-3}+n_{A-4})=40 to 80%,

n_{A-2}/(n_{A-1}+n_{A-2}+n_{A-3}+n_{A-4})=0 to 40%,

n_{A-3}/(n_{A-1}+n_{A-2}+n_{A-3}+n_{A-4})=0 to 40%, and

n_{A-4}/(n_{A-1}+n_{A-2}+n_{A-3}+n_{A-4})=0 to 40%.

As one embodiment of the present invention, n_{A-3}>0 and n_{A-4}=0, or n_{A-3}=0 and n_{A-4}>0 is preferable; n_{A-3}>0 and n_{A-4}=0 is more preferable.

The alkali-soluble resin (A) can also contain repeating units other than the repeating units represented by (A-1), (A-2), (A-3) and (A-4). Assuming that the total number of all repeating units contained in the alkali-soluble resin (A) is nₜₒₜₐₗ, following is satisfied:
(n_{A-1}+n_{A-2}+n_{A-3}+n_{A-4})/nₜₒₜₐₗ is preferably 80 to 100%; more preferably 90 to 100%; further preferably 95 to 100%; further more preferably 100%.

That is, it is also a preferable embodiment of the present invention that any structural units other than the repeating units represented by (A-1), (A-2), (A-3) and (A-4) are not contained.

Exemplified embodiments of the alkali-soluble resin (A) include the following:

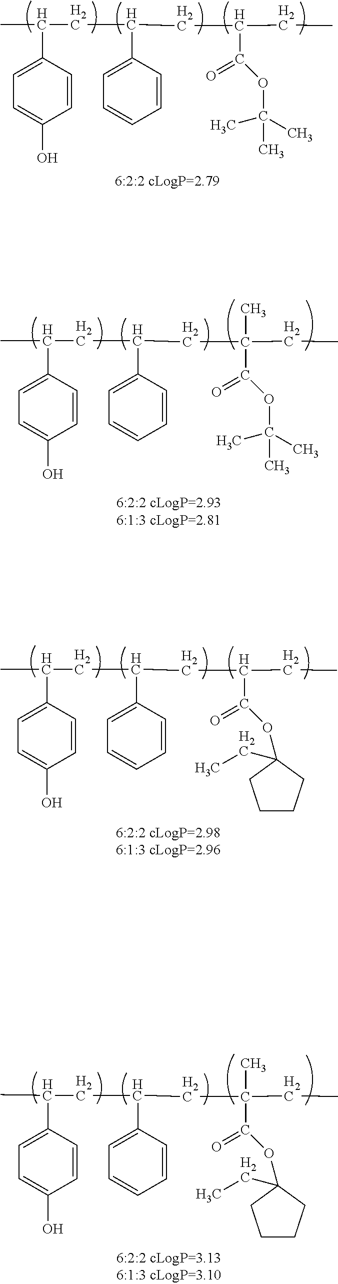

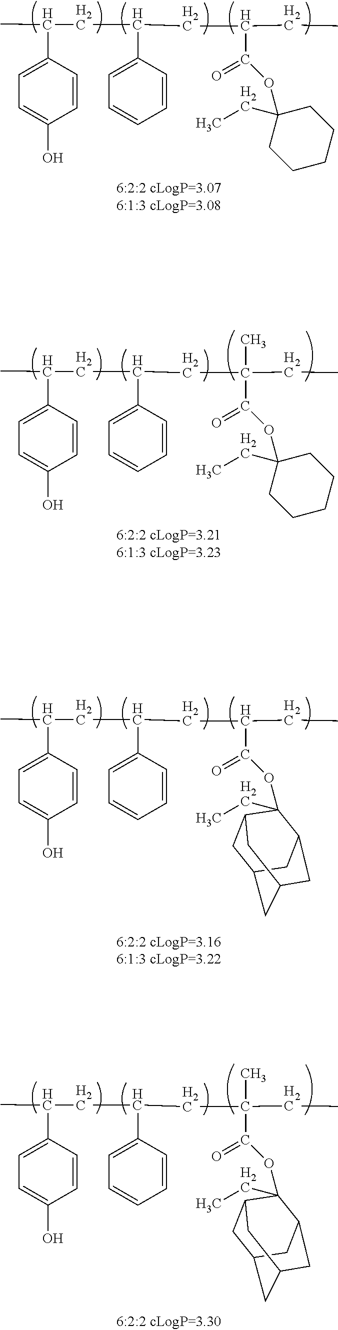

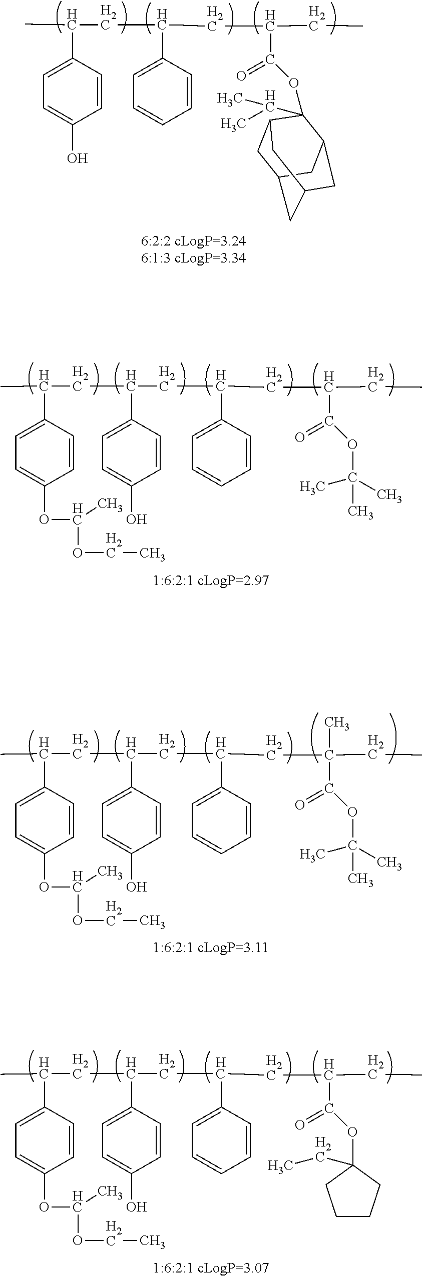

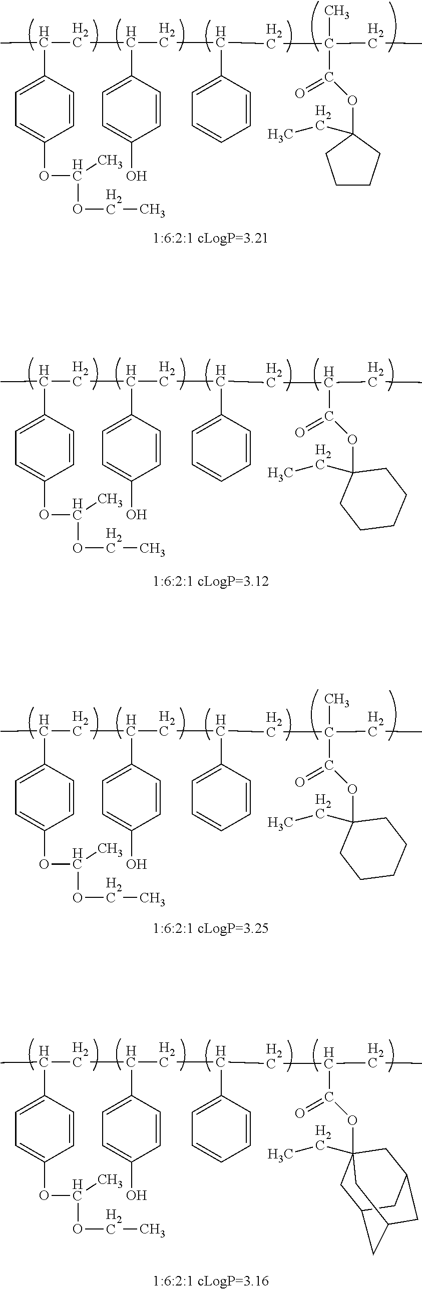

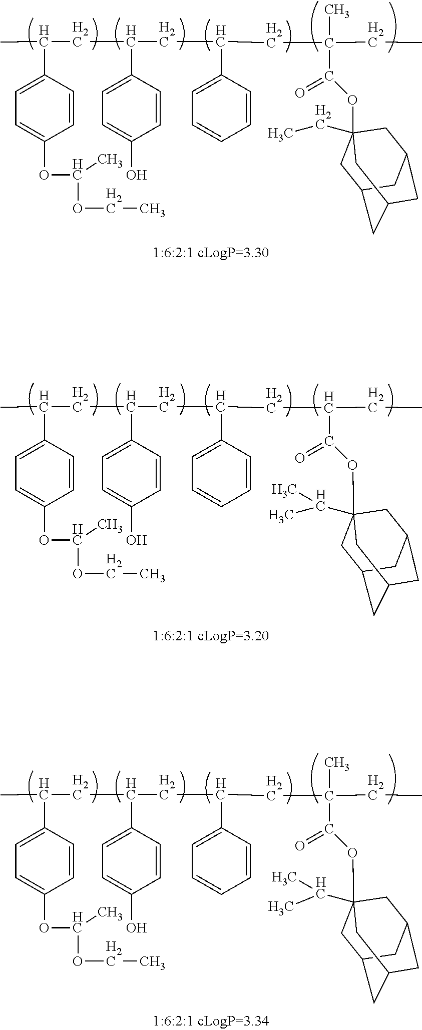

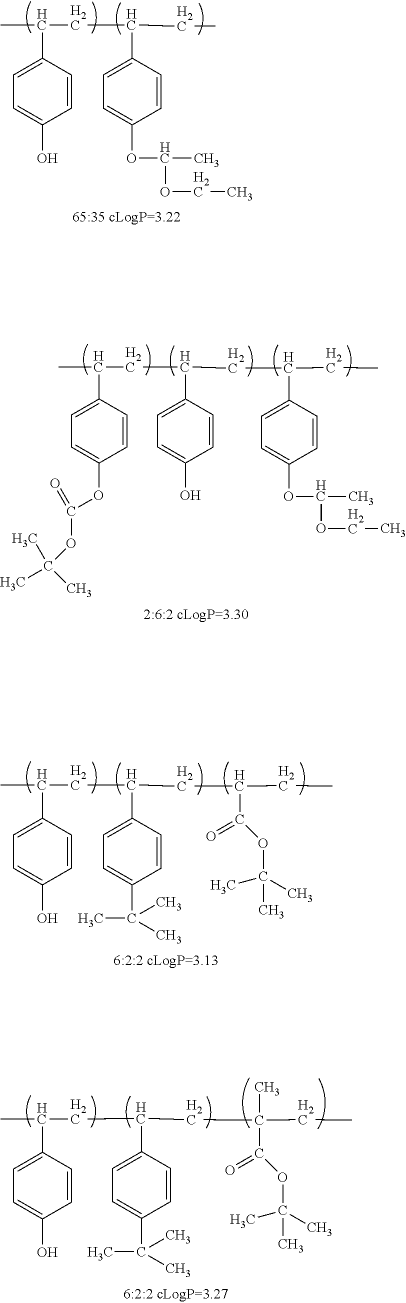

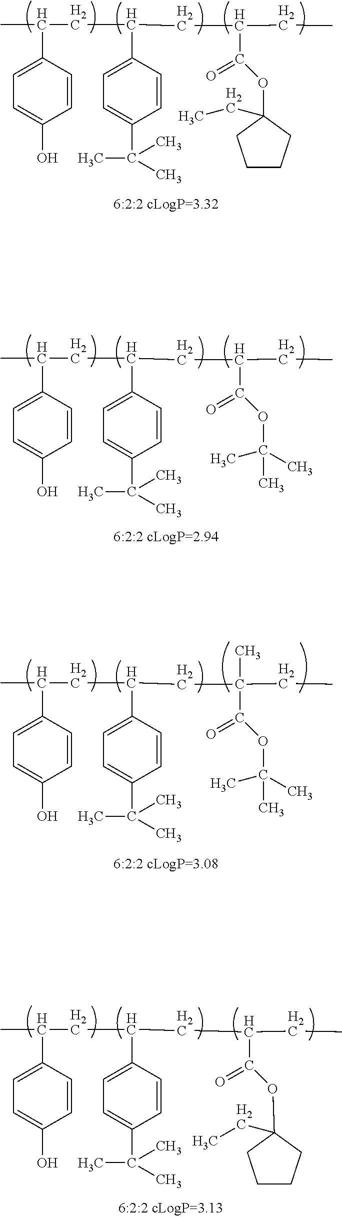

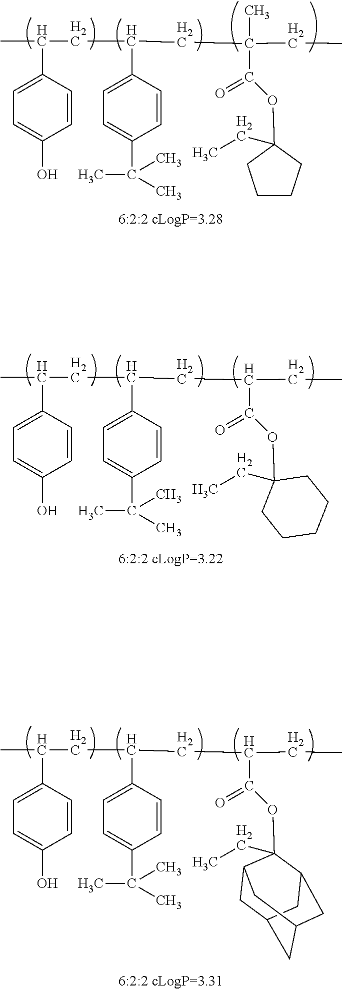

The mass average molecular weight (hereinafter sometimes referred to as Mw) of the alkali-soluble resin (A) is preferably 1,000 to 50,000; more preferably 2,000 to 30,000; further preferably 5,000 and 20,000; further more preferably 8,000 and 15,000.

The number average molecular weight of the alkali-soluble resin (A) (hereinafter sometimes referred to as Mn) is preferably 1,000 to 50,000; more preferably 2,000 to 30,000.

In the present invention, Mw and Mn can be measured by the gel permeation chromatography (GPC).

In this measurement, it is a preferable example to use a GPC column at 40° C., an eluent tetrahydrofuran at 0.6 mL/min and mono-dispersed polystyrene as a standard.

The following is described for explanation. In the composition of the present invention, these alkali-soluble resin (A) can be also used in combination of two or more types as long as they are represented by the above formulas. For example, a composition containing both of the following two types of alkali-soluble resin (A) together is also an embodiment of the present invention.

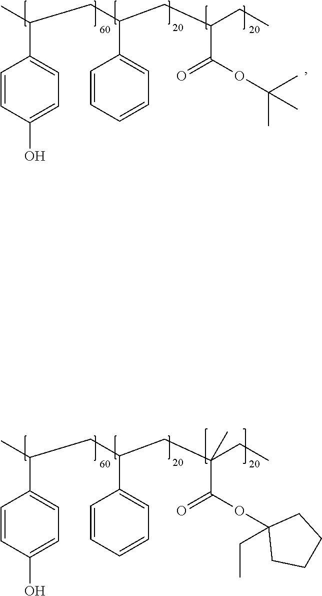

The same applies to the compositions of the present invention in the following description unless otherwise specified.
Preferably, the alkali-soluble resin (A) contained in the composition according to the present invention is composed of one or two types of polymer; more preferably, the alkali-soluble resin (A) is made of one type of polymer. Variations in Mw distribution and polymerization are allowed.

The content of the alkali-soluble resin (A) is preferably more than 0 mass % and 20 mass % or less; more preferably 3 to 15 mass %; further preferably 4 to 15 mass %, further more preferably 5 to 12 mass %, based on the composition.

The composition according to the present invention is allowed to contain polymer other than the alkali-soluble resin (A). The polymer other than the alkali-soluble resin (A) is polymer that contains no repeating units represented by the above formulas (A-1), (A-2), (A-3) and (A-4).

An embodiment that the composition contains no polymer other than the alkali-soluble resin (A) is one preferable embodiment.

### Photoacid Generator (B)

The composition according to the present invention comprises a photoacid generator (B). Here, the photoacid generator (B) releases an acid by irradiation with light. Preferably, the acid derived from the photoacid generator (B) acts on the alkali-soluble resin (A) to play a role in increasing the solubility of the alkali-soluble resin (A) in the alkaline aqueous solution. For example, when the alkali-soluble resin (A) has an acid group protected by a protective group, the protective group is eliminated by the acid. The photoacid generator (B) used in the composition according to the present invention can be selected from conventionally known ones.

The photoacid generator (B) releases, upon exposure, an acid having an acid dissociation constant pKa (H₂O) of preferably −20 to 1.4; more preferably −16 to 1.4; further preferably −16 to 1.2; further more preferably −16 to 1.1.

The photoacid generator (B) is preferably represented by the following formula (B-1) or formula (B-2); more preferably represented by the following formula (B-1):

The formula (B-1) is as follows.

Bⁿ⁺cation Bⁿ⁻anion (B-1)
wherein
the Bⁿ⁺cation is a cation represented by the formula (BC1), a cation represented by the formula (BC2) or a cation represented by the formula (BC3); preferably the cation represented by the formula (BC1). The Bⁿ⁺cation is n valent as a whole, and n is 1 to 3. The Bⁿ⁻anion is an anion represented by the formula (BA1), an anion represented by the formula (BA2), an anion represented by the formula (BA3) or an anion represented by the formula (BA4); preferably the anion represented by the formula (BA1) or the anion represented by the formula (BA2). The Bⁿ⁻anion is n valent as a whole.

n is preferably 1 or 2; more preferably 1.

The formula (BC1) is as follows:

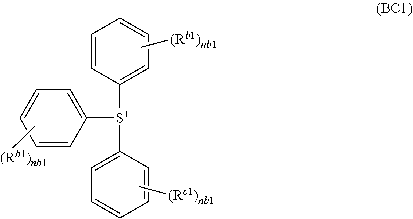

wherein
R^{b1} is each independently C₁₋₆ alkyl, C₁₋₆ alkoxy, C₆₋₁₂ aryl, C₆₋₁₂ arylthio or C₆₋₁₂ aryloxy, and nb1 is each independently 0, 1, 2 or 3.

R^{b1} is preferably methyl, ethyl, t-butyl, methoxy, ethoxy, phenylthio or phenyloxy; more preferably t-butyl, methoxy, ethoxy, phenylthio or phenyloxy.

It is also a preferable embodiment that all of nb1 are 1 and all of R^{b1} are identical. Further, it is also a preferable embodiment that all of nb1 are 0.

Exemplified embodiments of the formula (BC1) include the following:

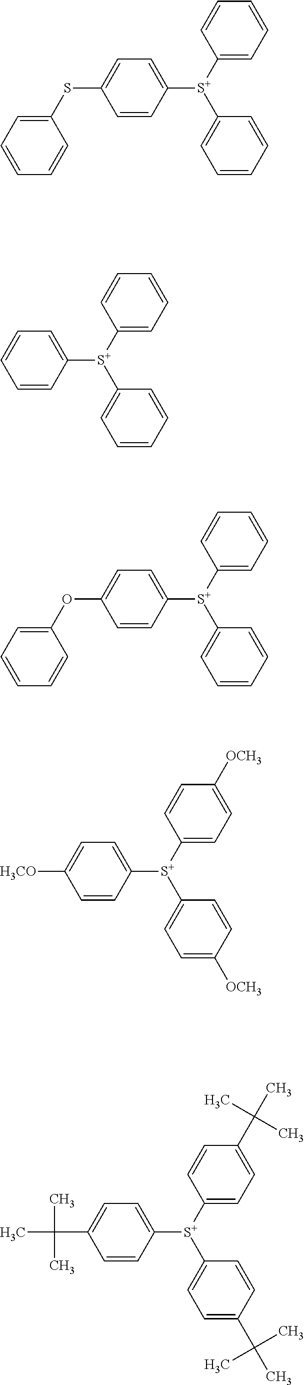 [SMILES: c1ccc(Sc2ccc([S+](c3ccccc3)c3ccccc3)cc2)cc1 ; c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1 ; CC(C)(C)c1ccc([S+](c2ccc(C(C)(C)C)cc2)c2ccc(C(C)(C)C)cc2)cc1]

The formula (BC2) is as follows:

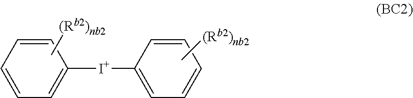

wherein
R^{b2} is each independently C₁₋₆ alkyl, C₁₋₆ alkoxy or C₆₋₁₂ aryl, and
nb2 is each independently 0, 1, 2 or 3.

R^{b2} is preferably alkyl having a C⁴⁻⁶ branched structure. Each Rb2 in the formula can be identical to or different from each other, and one in which they are identical to each other is more preferable. R^{b2} is further preferably t-butyl or 1,1-dimethylpropyl; further more preferably t-butyl.

It is preferable that nb2 is 1 each.

Exemplified embodiments of the formula (BC2) include the following:

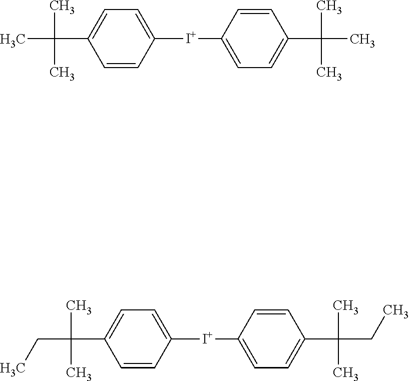

The formula (BC3) is as follows:

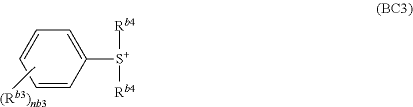

wherein
R^{b3} is each independently C₁₋₆ alkyl, C₁₋₆ alkoxy or C₆₋₁₂ aryl,
R^{b4} is each independently C₁₋₆ alkyl, and
nb3 is each independently 0, 1, 2 or 3.

R^{b3} is preferably each independently methyl, ethyl, methoxy or ethoxy, respectively; more preferably each independently methyl or methoxy.

R^{b4} is preferably methyl or ethyl; more preferably methyl.

nb3 is preferably 1, 2 or 3; more preferably 3.

An exemplified embodiment of the formula (BC3) includes the following:

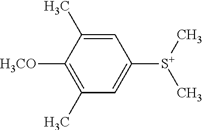

The formula (BA1) is as follows:

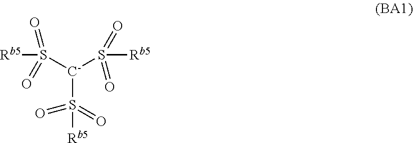

wherein
R^{b5} is each independently fluorine-substituted C₁₋₆ alkyl, fluorine-substituted C₁₋₆ alkoxy, or C₁₋₆ alkyl.

For example, —CF₃ means that all of hydrogen in methyl (CO is replaced with fluorine. The above-mentioned fluorine substitution means that a part or all of hydrogen existing in the alkyl moiety is replaced with fluorine, and more preferably all of hydrogen is replaced with fluorine.

The alkyl moiety of R^{b5} is preferably methyl, ethyl or t-butyl; more preferably methyl.

R^{b5} is preferably fluorine-substituted alkyl; more preferably —CF₃.

An exemplified embodiment of the formula (BA1) includes the following:

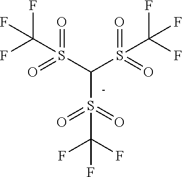 [SMILES: O=S(=O)(C(S(=O)(=O)C(F)(F)F)S(=O)(=O)C(F)(F)F)C(F)(F)F]

The formula (BA2) is as follows.

R^{b6}—SO₃⁻ (BA2)
wherein
R^{b6} is fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl.

For example, −CF₃ means that all of hydrogen in methyl (C₁) is replaced with fluorine. The above-mentioned fluorine substitution means that a part or all of hydrogen existing in the alkyl moiety is replaced with fluorine, and more preferably all of hydrogen is replaced with fluorine.

The alkyl moiety of R^{b6} is preferably linear. R^{b6} is preferably fluorine-substituted C₁₋₆ alkyl; more preferably fluorine-substituted C₂₋₆ alkyl. The alkyl moiety of R^{b6} is preferably methyl, ethyl, propyl, butyl or pentyl; more preferably propyl, butyl or pentyl; further more preferably butyl.

Exemplified embodiments of the formula (BA2) include the following:

C₄F₉SO₃_{^{−}}, C₃F₇SO₃_{^{−}}

The formula (BA3) is as follows:

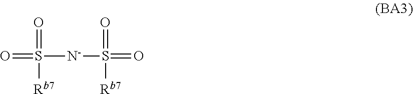

wherein
R^{b7} is each independently fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl; preferably fluorine-substituted C₂₋₆ alkyl.

For example, —CF₃ means that all of hydrogen in methyl (C₁) is replaced with fluorine. The above-mentioned fluorine substitution means that a part or all of hydrogen existing in the alkyl moiety is replaced with fluorine, and more preferably all of hydrogen is replaced with fluorine.

Two R^{b7} can be bonded to each other to form a fluorine-substituted heterocyclic structure. The heterocyclic structure is preferably a saturated ring. The heterocyclic structure, including N and S, is preferably a 5- to 8-membered monocyclic structure; more preferably a five- or six-membered ring; further more preferably a six-membered ring.

The alkyl moiety of R^{b7} is preferably methyl, ethyl, propyl, butyl or pentyl; more preferably methyl, ethyl or butyl; further preferably butyl. The alkyl moiety of R^{b6} is preferably linear.

Exemplified embodiments of the formula (BA3) include the following:

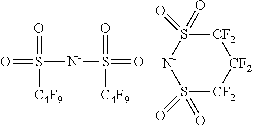

The formula (BA4) is as follows:

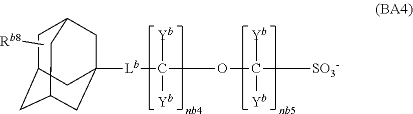

wherein
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21.

R^{b8} is preferably hydrogen, methyl, ethyl, methoxy, or hydroxy; more preferably hydrogen or hydroxy.

L^{b} is preferably carbonyl or carbonyloxy; more preferably carbonyl.

Preferably, at least one or more of Yb is fluorine.

nb4 is preferably 0.

nb5 is preferably 4, 5 or 6.

Exemplified embodiments of the formula (BA4) include the following:

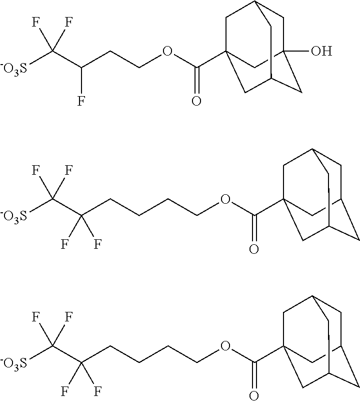

The formula (B-2) is as follows:

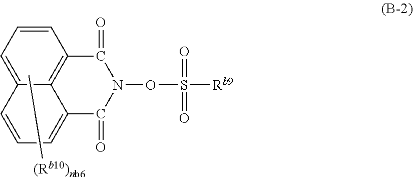

wherein
R^{b9} is fluorine-substituted C₁₋₅ alkyl.

The above-mentioned fluorine substitution means that a part or all of hydrogen existing in the alkyl moiety is replaced with fluorine, and more preferably all of hydrogen is replaced with fluorine.

R^{b10} is each independently C₃₋₁₀ alkenyl or alkynyl (where CH₃— in the alkenyl and alkynyl can be replaced with phenyl, and —CH₂— in the alkenyl and alkynyl can be replaced with at least one of —C(═O)—, —O— or phenylene), C₂₋₁₀ thioalkyl, or C₅₋₁₀ saturated heterocycle. Here, in the present invention, alkenyl means a monovalent group having one or more double bonds (preferably one). Similarly, alkynyl means a monovalent group having one or more triple bonds (preferably one).

nb6 is 0, 1 or 2.

R^{b9} is preferably C₁₋₄ alkyl in which all of hydrogen are fluorine-substituted; more preferably, C₁ or C₄ alkyl in which all of hydrogen are fluorine-substituted. The alkyl in R^{b9} is preferably linear.

R^{b10} is preferably C₃₋₁₂ alkenyl or alkynyl (where CH₃— in the alkenyl and alkynyl can be replaced with phenyl and —CH₂— in the alkenyl and alkynyl can be replaced with at least one of —C(═O)—, —O— or phenylene), C₃₋₅ thioalkyl, or C₅₋₆ saturated heterocycle.

Exemplified embodiments of R^{b10} include —C≡C—CH₂—CH₂—CH₂—CH₃, —CH═CH—C(═O)—O-tBu, —CH═CH—Ph, —S—CH(CH₃)₂, —CH═CH—Ph—O—CH(CH₃)(CH₂CH₃) and piperidine. Here, tBu means t-butyl and Ph means phenylene or phenyl. Hereinafter, the same applies unless otherwise specified.

nb6 is preferably 0 or 1; 0 is more preferred. It is also a preferable embodiment that nb6=1.

Exemplified embodiments of the formula (B-2) include the following:

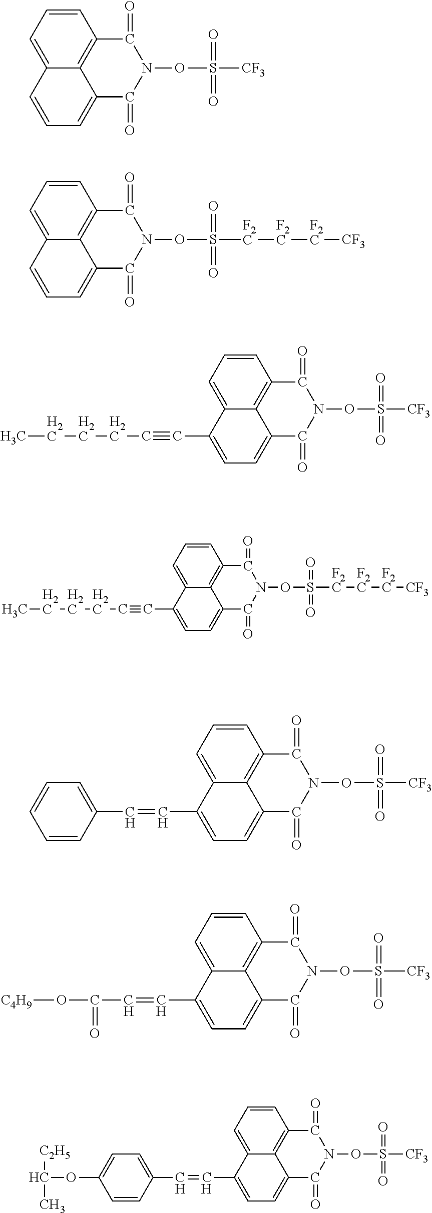

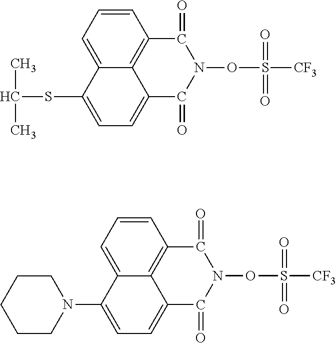 [SMILES: CC(C)Sc1ccc2c3c(cccc13)C(=O)N(OS(=O)(=O)C(F)(F)F)C2=O ; O=C1c2cccc3c(N4CCCCC4)ccc(c23)C(=O)N1OS(=O)(=O)C(F)(F)F]

The molecular weight of the photoacid generator (B) is preferably 400 to 2,500; more preferably 400 to 1,500.

The content of the photoacid generator (B) is preferably more than 0 mass % and 20 mass % or less; more preferably 0.5 to 10 mass %, further preferably 1 to 5 mass %; further more preferably 2 to 4 mass %, based on the alkali-soluble resin (A).

### Solvent (C)

The composition according to the present invention comprises a solvent (C). The solvent is not particularly limited as long as it can dissolve each component to be compounded. The solvent (C) is preferably water, a hydrocarbon solvent, an ether solvent, an ester solvent, an alcohol solvent, a ketone solvent, or a combination of any of these.

Exemplified embodiments of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonane, cyclohexanone, cyclopentanone, methylcyclohexanone, 2,4-pentanedione, acetonylacetone, diacetone alcohol, acetophenone, fenthion, ethyl ether, i-propyl ether, n-butyl ether (di-n-butyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of two or more of these.

The solvent (C)) is preferably PGME, PGMEA, EL, nBA, DBE or a mixture of any of these; more preferably PGME, EL, nBA, DBE or a mixture of any of these; further preferably PGME, EL or a mixture of any of these; further more preferably a mixture of PGME and EL. When two types are mixed, the mass ratio of the first solvent to the second solvent is preferably 95:5 to 5:95 (more preferably 90:10 to 10:90; further preferably 80:20 to 20:80). When three types are mixed, the mass ratio of the first solvent to the sum of the three types is 30 to 90% (more preferably 50 to 80%; further preferably 60 to 70%), the mass ratio of the second solvent to the sum of the three types is 10 to 50% (more preferably 20-40%), and the mass ratio of the third solvent to the sum of the three types is 5 to 40% (more preferably 5 to 20%; further preferably 5 to 15%).

In relation to other layers or films, it is also one embodiment that the solvent (C) substantially contains no water. For example, the amount of water in the total solvent (C) is preferably 0.1 mass % or less; more preferably 0.01 mass % or less; further preferably 0.001 mass % or less. It is also a preferable embodiment that the solvent (C) contains no water (0 mass %).

The content of the solvent (C) is 80 mass % or more and less than 100 mass %; more preferably 80 to 95 mass %; further preferably 85 to 95 mass %, based on the composition. By increasing or decreasing the amount of the solvent occupying in the entire composition, the film thickness after film formation can be controlled.

### Photoacid Generator (D)

The composition according to the present invention preferably further comprises a photoacid generator (D) represented by the following formula (D-1). In the present invention, the photoacid generator (D) is different from the photoacid generator (B). As a preferred embodiment of the present invention, the acid that acts directly on the alkali-soluble resin (A) is the acid released from not the photoacid generator (D) but the photoacid generator (B).

As a preferred embodiment of the present invention, the cation derived from the photoacid generator (D) reacts with the anion moiety derived from the photoacid generator (B) and functions as a quencher. In this case, the photoacid generator (D) acts as a quencher that suppresses the diffusion of the acid generated in the exposed region, which is derived from the photoacid generator (B). Without wishing to be bound by theory, it can be considered as the following mechanism. Upon exposure, an acid is released from the photoacid generator (B), and when this acid diffuses into the unexposed region, salt exchange with the photoacid generator (D) occurs. That is, the anion of the photoacid generator (B) and the cation of the photoacid generator (D) make a salt. As a result, the diffusion of acid is suppressed. At this time, the anion of the photoacid generator (D) is released, but since this is a weak acid and the polymer cannot be deprotected, it is considered that the unexposed region is not affected.

Furthermore, the photoacid generator (D) has an effect of suppressing the deactivation of the acid on the surface of the resist film due to components contained in the air, such as amine. Without wishing to be bound by theory, it can be considered as the following mechanism. In the exposed region, acids (a weak acid derived from the photoacid generator (D) and an acid derived from the photoacid generator (B)) are generated upon exposure. When the amine in the air permeates the surface of the resist film, the acid present therein is neutralized. However, the presence of the weak acid released from the photoacid generator (D) reduces the frequency with which the acid released from the photoacid generator (B) is neutralized. It is considered that the deactivation of the acid is suppressed by increasing the acid in the exposed region in this way.

In order to obtain the above two effects, for example, a basic compound such as a tertiary amine can be added. When the composition contains the photoacid generator (D), the above two effects tend to become higher and the sensitivity tends to become higher than when the composition contains the basic compound. Without wishing to be bound by theory, when a basic compound is added as a quencher for the acid that diffuses from an exposed region to an unexposed region, it is considered that the acid is neutralized (quenched) also in the exposed region. Without wishing to be bound by theory, when a basic compound is added to suppress the inactivation of acid on the surface of the resist film due to the influence of components contained in the air, such as amine, the basic composition already exists in the film, so that the amount of amine that has permeated from the air is relatively reduced. On the other hand, the permeation of amine and the like present in the air is not intentionally controlled. In this way, it is considered that using the photoacid generator (D) as in the present invention is preferable for resist pattern design and stable production. As described above, the supposed mechanism of action differs depending on whether the basic compound is added or the photoacid generator (D) is added.

Without wishing to be bound by theory, it is considered that when the photoacid generator (D) is a solid, a stabler effect can be obtained because it has better dispersibility in the film than the basic compound.

The photoacid generator (D) is represented by the formula (D-1):

D^{m+}cation D^{m-}anion (D-1)
wherein
the D^{m+}cation is a cation represented by the formula (DC1) or a cation represented by the formula (DC2); preferably the cation represented by the formula (DC1).

The D^{m+}cation is m valent as a whole, and m is 1 to 3.

The D^{m-}anion is an anion represented by the formula (DA1) or an anion represented by the formula (DA2); preferably the anion represented by the formula (DA1). The D^{m-}anion is m valent as a whole.

m is preferably 1 or 2; more preferably 1.

The formula (DC1) is as follows:

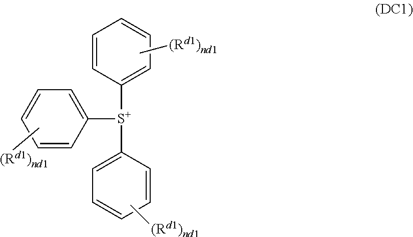

wherein
R^{d1} is each independently C₁₋₆ alkyl, C₁₋₆ alkoxy or C₆₋₁₂ aryl, and
nd1 is each independently 0, 1, 2 or 3.

R^{d1} is preferably methyl, ethyl, t-butyl, methoxy, ethoxy, phenylthio or phenyloxy; more preferably t-butyl, methoxy, ethoxy, phenylthio or phenyloxy; further preferably t-butyl or methoxy.

nd1 is preferably 0 or 1; more preferably 0.

It is also a preferable embodiment that all of nd1 are 1 and all of R^{d1} are identical to each other.

Exemplified embodiments of the formula (DC1) include the following:

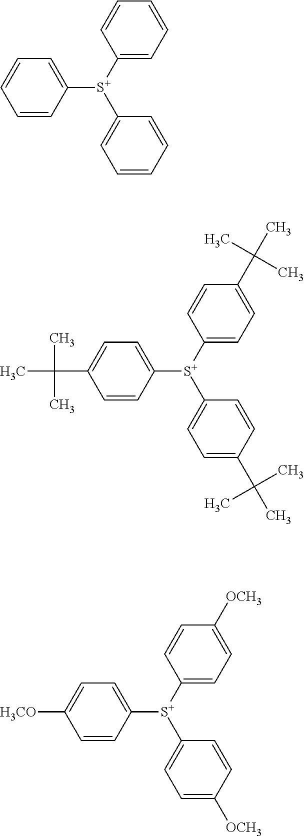 [SMILES: c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccc(OC)cc2)c2ccc(OC)cc2)cc1]

The formula (DC2) is as follows.

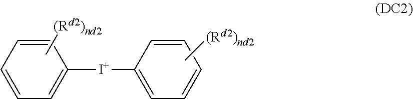

wherein
R^{d2} is each independently C₁₋₆ alkyl, C₁₋₆ alkoxy or C₆₋₁₂ aryl, and
nd2 is each independently 0, 1, 2 or 3

R^{d2} is preferably alkyl having a C₄₋₆ branched structure. Each R^{d2} in the formula can be identical to or different from each other, and it is more preferable that they are identical to each other. R^{d2} is further preferably t-butyl or 1,1-dimethylpropyl; further more preferably t-butyl.

It is preferable that nd2 is 1 each.

Exemplified embodiments of the formula (DC2) include the following:

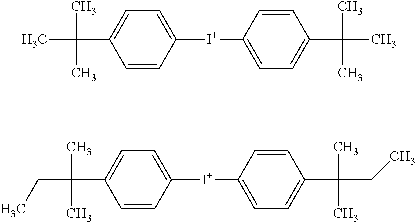

The formula (DA1) is as follows.

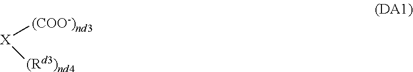

wherein
X is C₁₋₂₀ hydrocarbon or a single bond,
Rd³ is each independently hydrogen, hydroxy, C₁₋₆ alkyl, or C₆₋₁₀ aryl,
nd3 is 1, 2 or 3, and
nd4 is 0, 1 or 2.

When X is hydrocarbon, it can be any of linear, branched or cyclic, but it is preferably linear or cyclic. In the case of linear, it is preferably C₁₋₄ (more preferably C₁₋₂), and preferably has one double bond in the chain or is saturated. When it is cyclic, it can be an aromatic monocyclic ring, or a saturated monocyclic ring or polycyclic ring. When it is monocyclic, it is preferably a 6-membered ring, and when it is polycyclic, it is preferably an adamantane ring.

X is preferably methyl, ethyl, propyl, butyl, ethane, phenyl, cyclohexane, adamantan or a single bond; more preferably methyl, phenyl, cyclohexane or a single bond; further preferably phenyl or a single bond; further more preferably phenyl.

nd3 is preferably 1 or 2; more preferably 1.

nd4 is preferably 0 or 1; more preferably 1.

R^{d3} is preferably hydroxy, methyl, ethyl, 1-propyl, 2-propyl, t-butyl or phenyl; more preferably hydroxy.

When X is a single bond, R^{d3} is preferably hydrogen. The formula (DA1) in which X is a single bond, R^{d3} is hydrogen, and nd3=nd4=1 represents an anion being H—COO—.

Exemplified embodiments of the formula (DA1) include the following:

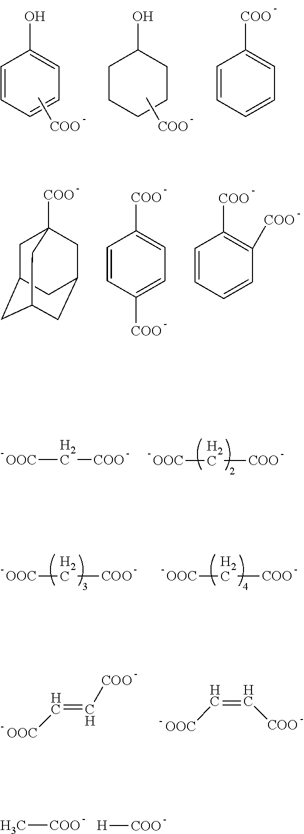

The formula (DA2) is as follows.

R^{d4}—SO₃⁻ (DA2)
wherein
R^{d4} is C₁₋₁₅ alkyl (where a part or all of the alkyl can form a ring and —CH₂— in the alkyl can be replaced with —C(═O)—).

R^{d4} is preferably C₃₋₁₃ alkyl; more preferably C₅₋₁₂ alkyl; further preferably C₈₋₁₂ alkyl; further more preferably C₁₀ alkyl. The alkyl of R^{d4} preferably forms a ring in part or in whole; more preferably in part. Preferably, one or more (more preferably 1) —CH₂— in the alkyl of R_{d4} is replaced with —C(═O)—.

An exemplified embodiment of the formula (DA2) includes the following:

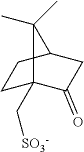

The photoacid generator (D) releases, upon exposure, an acid having an acid dissociation constant pKa (H₂O) of 1.5 to 8; more preferably 1.5 to 5.

The molecular weight of the photoacid generator (D) is preferably 300 to 1,400; more preferably 300 to 1,200.

The content of the photoacid generator (D) is preferably 0.01 to 5 mass %; more preferably 0.03 to 1 mass %; further preferably 0.05 to 1 mass %; further more preferably 0.5 to 1 mass %, based on the alkali-soluble resin (A).

### Basic Compound (E)

The composition according to the present invention can further comprise a basic compound (E). The basic compound has an effect of suppressing the diffusion of the acid generated in the exposed region and an effect of suppressing the inactivation of the acid on the surface of the resist film by the amine component contained in the air. In the composition according to the present invention, as described above, the photoacid generator (D) can exhibit these effects, so that the combined use of the photoacid generator (D) and the basic compound (E) is not essential.

The basic compound (E) preferably includes ammonia, C₁₋₁₆ primary aliphatic amine compound, C₂₋₃₂ secondary aliphatic amine compound, C₃₋₄₈ tertiary aliphatic amine compound, C₆₋₃₀ aromatic amine compound or C₅₋₃₀ heterocyclic amine compound.

Exemplified embodiments of the basic compound (E) include ammonia, ethylamine, n-octylamine, n-heptylamine, ethylenediamine, triethylamine, tri-n-octylamine, diethylamine, triethanolamine tris[2-(2-methoxyethoxy)ethyl amine, 1,8-diazabicyclo[5.4.0]-undecene-7, 1,5-diazabicyclo[4.3.0]nonen-5, 7-methyl-1,5,7-triazabicyclo[4.4.0]deca-5-ene and 1,5,7-triaza-bicyclo[4.4.0]deca-5-ene.

The base dissociation constant pKb (H₂O) of the basic compound (E) is preferably −12 to 5; more preferably 1 to 4.

The molecular weight of the basic compound (E) is preferably 17 to 500; more preferably 60 to 400.

The content of the basic compound (E) is preferably 0.01 to 3 mass %; more preferably 0.05 to 1 mass %; further preferably 0.1 to 0.5 mass %. Considering the storage stability of the composition, it is also a preferable embodiment that the composition contains no basic compound (E).

### Surfactant (F)

The lithography composition according to the present invention preferably comprises a surfactant (F). The coatability can be improved by making a surfactant be comprised in the lithography composition according to the present invention. Examples of the surfactant that can be used in the present invention include (I) anionic surfactants, (II) cationic surfactants or (III) nonionic surfactants, and more particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether and fluorine-containing surfactants (for example, Fluorad (3M), Megafac (DIC), Surflon (AGC) and organic siloxane surfactants (for example, KF-53 and KP341 (Shin-Etsu Chemical)).

These surfactants can be used alone or in combination of two or more of these. The content of the surfactant (F) based on the alkali-soluble resin (A) is preferably more than 0 mass % and 1 mass % or less; more preferably 0.005 to 0.5 mass %; further preferably 0.01 to 0.2 mass %.

### Additive (G)

The composition according to the present invention can further comprise an additive (G). The additive (G) is preferably at least one selected from the group consisting of a surface smoothing agent, a plasticizer, a dye, a contrast enhancer, an acid, a radical generator, a substrate adhesion enhancer and an antifoaming agent.

The content of the additive (G) (in the case of a plurality, the sum thereof) based on the alkali-soluble resin (A) is preferably 0 to 20 mass %; more preferably 0.001 to 15 mass %; further preferably 0.1 to 10 mass %. It is also one of the embodiments of the present invention that the composition according to the present invention contains no additive (G) (0 mass %).

By including a surface smoothing agent, the side surface of the resist pattern can be smoothed, which contributes to the improvement of LER (Line Edge Roughness) and LWR (Line Width Roughness).

The surface smoothing agent is preferably represented by the following formula:

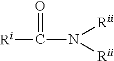

wherein
Rⁱ is hydrogen, C₁₋₆ alkyl, C₃₋₁₀ alkenyl (where CH₃— in the alkenyl can be replaced with phenyl) or C₆₋₁₀ aryl; preferably hydrogen, methyl, ethyl, propenyl, phenyl or trill.

Rⁱⁱ is each independently C₁₋₆ alkyl or C₆₋₁₀ aryl; preferably methyl, ethyl or phenyl.

Examples of the surface smoothing agent are as follows:

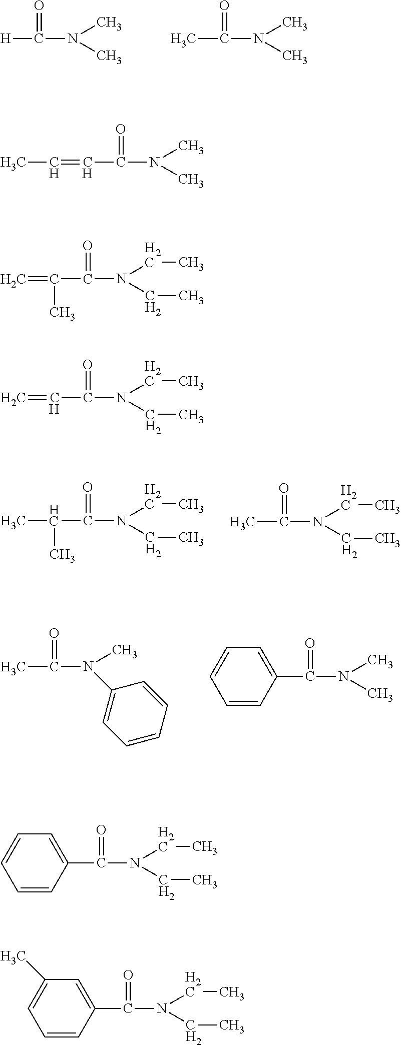

The content of the surface smoothing agent based on the alkali-soluble resin (A) is preferably 0 to 20 mass %; more preferably 0.001 to 10 mass %; further preferably 0.1 to 10 mass %; further more preferably 3 to 10 mass %.

By including a plasticizer, film cracking during thick film formation can be suppressed.

Examples of the plasticizer include alkali-soluble vinyl polymer and acid-dissociating group-containing vinyl polymer. More particular examples include polyvinyl chloride, polystyrene, polyhydroxystyrene, polyvinyl acetate, polyvinyl benzoate, polyvinyl ether, polyvinyl butyral, polyvinyl alcohol, polyether ester, polyvinylpyrrolidone, polyacrylic acid, polymethacrylic acid, polyacrylic ester, polymaleimide, polyacrylamide, polyacrylonitrile, polyvinylphenol, novolak, and copolymer thereof, and polyvinyl ether, polyvinyl butyral and polyether ester are more preferable.

Exemplified embodiments of the plasticizer include the following:

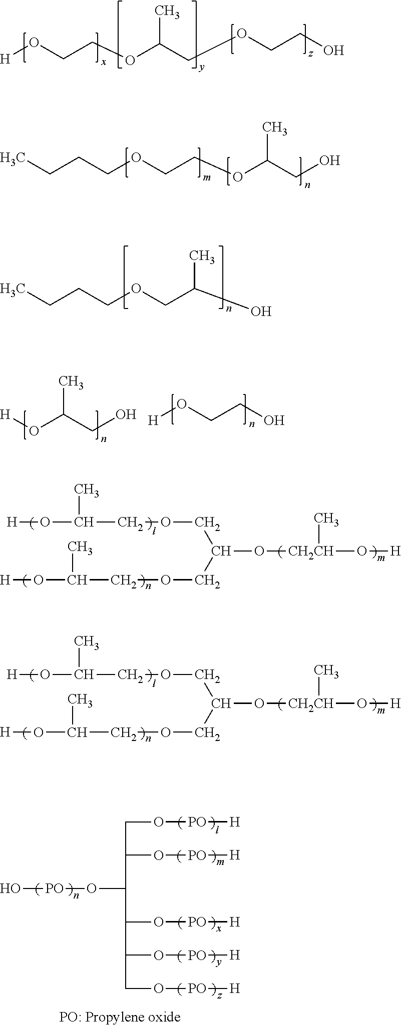

The mass average molecular weight of the plasticizer is preferably 1,000 to 50,000; more preferably 1,500 to 30,000; further preferably 2,000 to 21,000; further more preferably 2,000 to 15,000.

The content of the plasticizer based on the alkali-soluble resin (A) is preferably 0 to 20 mass %; more preferably 0 to 17 mass %. It is also a preferred embodiment of the present invention that it contains no plasticizer (0 mass %).

By including a dye, the pattern shape can be improved. The dye is not particularly limited as long as it is a compound having an appropriate absorption at an exposure wavelength. Examples thereof include benzene, naphthalene, anthracene, phenanthrene, pyrene, isocyanuric acid, triazine, and their derivatives.

Examples of the contrast enhancer include compounds having a low molecular weight, which are derived from an alkali-soluble phenolic compound or a hydroxycyclocyclic compound and contain an acid-labile group (hereinafter referred to as leaving group). Here, the leaving group reacts with the acid released from the deprotecting agent to break away from the compound, and the solubility of the compound in the alkaline aqueous solution increases, so that the contrast becomes larger. Such a leaving group is, for example, —R^{r1}, —COOR^{r1} or —R^{r2}—COOR^{r1} (where R^{r1} is a linear, branched or cyclic alkyl group having 1 to 10 carbon atoms, which can contain an oxygen atom between carbon and carbon, and R^{r2} is an alkylene group having 1 to 10 carbon atoms), which can be replaced with hydrogen in the hydroxyl group bonded to the compound. Such a contrast enhancer preferably contains two or more leaving groups in the molecule. Further, the mass average molecular weight is 3,000 or less; preferably 100 to 2,000. Preferred compounds before introducing a leaving group into the hydroxyl group are as follows:

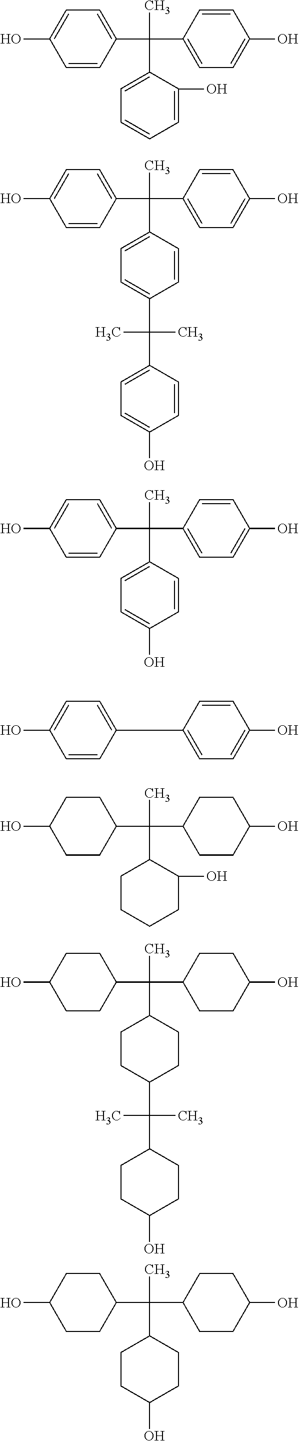

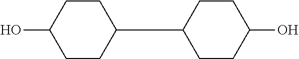 [SMILES: OC1CCC(CC2CCC(O)CC2)CC1]

These contrast enhancers can be used alone or in combination of any two or more, and the content thereof based on the alkali-soluble resin (A) is preferably 0.5 to 40 mass %; more preferably 1 to 20 mass %.

The acid can be used to adjust the pH value of the composition and improve the solubility of the additive components. The acid used is not particularly limited, but examples thereof include formic acid, acetic acid, propionic acid, benzoic acid, phthalic acid, salicylic acid, lactic acid, malic acid, citric acid, oxalic acid, malonic acid, succinic acid, fumaric acid, maleic acid, aconitic acid, glutaric acid, adipic acid, and combinations thereof. The content of the acid based on the composition is preferably 0.005 mass % or more and 0.1 mass % or less (50 ppm to 1,000 ppm).

By using a substrate adhesion enhancer, it is possible to prevent the pattern from being peeled off due to the stress applied during film formation. As the substrate adhesion enhancer, imidazoles and silane coupling agents are preferable, and as the imidazoles, 2-hydroxybenzoimidazole, 2-hydroxyethylbenzo-imidazole, benzoimidazole, 2-hydroxyimidazole, imidazole, 2-mercaptoimidazole and 2-aminoimidazole are preferable, and 2-hydroxybenzoimidazole, benzoimidazole, 2-hydroxyimidazole and imidazole are more preferably used. The content of the substrate adhesion enhancer based on the alkali-soluble resin alkali-soluble resin (A) is preferably 0 to 2 mass %; more preferably 0 to 1 mass %.

### Method for Manufacturing a Resist Film

The method for manufacturing a resist film according to the present invention comprises the following steps:
(1) applying the composition according to the present invention above a substrate; and
(2) heating the composition to form a resist film.

Hereinafter, one embodiment of the manufacturing method according to the present invention is described.

The composition according to the present invention is applied above a substrate (for example, a silicon/silicon dioxide coated substrate, a silicon nitride substrate, a silicon wafer substrate, a glass substrate, an ITO substrate, and the like) by an appropriate method. Here, in the present invention, the “above” includes the case where a layer is formed immediately above a substrate and the case where a layer is formed above a substrate via another layer. For example, a planarization film or resist underlayer can be formed immediately above a substrate, and the composition according to the present invention can be applied immediately above the film. As the resist underlayer film, a BARC layer is included. The application method is not particularly limited, and examples thereof include a method using a spinner or a coater. After application, the film according to the present invention is formed by heating. The heating of the step (2) is performed, for example, by a hot plate. The heating temperature is preferably 100 to 250° C.; more preferably 100 to 200° C.; further preferably 100 to 160° C. The temperature here is a temperature of heating atmosphere, for example, that of a heating surface of a hot plate. The heating time is preferably 30 to 300 seconds; more preferably 30 to 120 seconds; further more preferably 45 to 90 seconds. The heating is preferably performed in an air or a nitrogen gas atmosphere.

The film thickness of the resist film is selected depending on the purpose, but in the case that the composition according to the present invention is used, a pattern having a better shape can be formed when forming a thin film coating film. The thickness of the resist film is preferably 50 to 2,000 nm; more preferably 50 to 1,000 nm; further preferably 50 to 500 nm; further more preferably 50 to 400 nm.

A resist pattern can be manufactured by a method further comprising the following steps:
(3) exposing the resist film; and
(4) developing the resist film.

Although describing for clarity, the steps (1) and (2) are performed before the step (3). The numbers in parentheses indicating the step mean the order. The same applies hereinafter.

The resist film is exposed through a predetermined mask. The wavelength of light to be used for exposure is not particularly limited, but it is preferable to expose with light having a wavelength of 13.5 to 248 nm. In particular, KrF excimer laser (wavelength: 248 nm), ArF excimer laser (wavelength: 193 nm), extreme ultraviolet ray (wavelength: 13.5 nm), or the like can be used, and KrF excimer laser is preferable. These wavelengths allow a range of ±1%. After exposure, post exposure bake (PEG) can be performed, as necessary. The temperature for PEG is preferably 80 to 160° C.; more preferably 100 to 150° C., and the heating time is 0.3 to 5 minutes; preferably 0.5 to 2 minutes.

The exposed resist film is developed with a developper. As the developing method, a method conventionally used for developing a photoresist, such as a paddle developing method, an immersion developing method, or a swinging immersion developing method, can be used. Further, as the developer, aqueous solution containing inorganic alkalis, such as sodium hydroxide, potassium hydroxide, sodium carbonate and sodium silicate; organic amines, such as ammonia, ethylamine, propylamine, diethylamine, diethylaminoethanol and triethylamine; quaternary amines, such as tetramethylammonium hydroxide (TMAH); and the like are used, and a 2.38 mass % TMAH aqueous solution is preferable. A surfactant can be further added to the developer. The temperature of the developer is preferably 5 to 50° C., more preferably 25 to 40° C., and the development time is preferably 10 to 300 seconds, more preferably 30 to 60 seconds. After development, washing or rinsing treatment can also be performed, as necessary. When a positive type resist composition is used, the exposed region is removed by development to form a resist pattern. The resist pattern can also be further made finer, for example, using a shrink material.

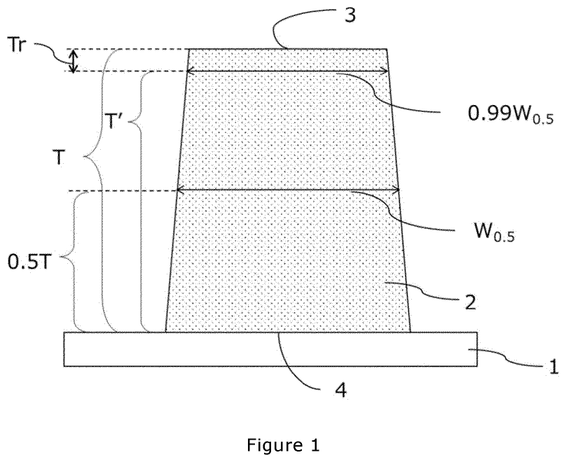

When the composition according to the present invention is used, a resist pattern having high rectangularity is formed. As a preferred embodiment of the manufacturing method of the present invention, assuming that the height from the top to the bottom of the resist pattern to be manufactured is T, the resist width at the height from the bottom of the resist pattern of 0.5 T is W_{0.5}, the height at which resist width is 0.99 W_{0.5} is T′, and the difference between the height T and the height T′ is Tr, Tr/T is preferably 0 to 25%; more preferably 5 to 25%.; further preferably 5 to 15%; further more preferably 5 to 12%. FIG. 1 is a cross-sectional view of a resist pattern of one embodiment of the present invention. A resist pattern 2 is formed on the substrate 1. The height of the resist top 3 with respect to the resist bottom 4 is T. With respect to this T, the resist width of the resist pattern at a height of 0.5 T is taken as W_{0.5}. The higher the height becomes, the smaller the resist width becomes, and the height at which the resist width becomes 0.99×W_{0.5} is taken as T′, and the difference between the height T and the height T′ is taken as Tr. At this time, Tr/T is preferably 0 to 25%.

Further, the conditions for comparing these numerical values are preferably measured aligning to the examples described later as much as possible. For example, it is preferable to form a film having a film thickness of 400 nm and form a resist pattern having 1:1 trench of 180 nm, and then be subjected to comparison.

A processed substrate can be manufactured by a method further comprising the following step:
(5) processing using the resist pattern as a mask.

The formed resist pattern is preferably used for processing the underlayer film or the substrate (more preferably the substrate). In particular, using the resist pattern as a mask, various substrates being a base can be processed using a dry etching method, a wet etching method, an ion implantation method, a metal plating method, or the like.

When processing the underlayer film using the resist pattern, the processing can be performed step by step. For example, a BARC layer can be processed using a resist pattern, a SOC film can be processed using the formed BARC pattern, and a substrate can be processed using the formed SOC pattern.

A wiring can also be formed in the gap formed by processing the substrate.

Thereafter, if necessary, the substrate is further processed to form a device. For these further processings, known methods can be applied. After forming the device, if necessary, the substrate is cut into chips, which are connected to a lead frame and packaged with resin. In the present invention, this packaged product is referred to as device. Examples of the device include a semiconductor device, a liquid crystal display device, an organic EL display device, a plasma display device, and a solar cell device. The device is preferably a semiconductor.

### EXAMPLES

The present invention is described below with reference to various examples. The embodiments of the present invention are not limited only to these examples.

### Preparation of Composition 1

100 parts by mass of polymer 1, 2.85 parts by mass of photoacid generator B1, 0.14 parts by mass of photoacid generator D1, 4 parts by mass of basic compound 1 and 0.06 parts by mass of surfactant 1 are added to a mixed solvent having a mass ratio of PGME:EL=70:30 so that the solid content ratio becomes 7.31 mass %. This is stirred at room temperature for 30 minutes. It is visually confirmed that the added materials are dissolved. This is filtered through a 0.05 μm filter. This gives Composition 1.

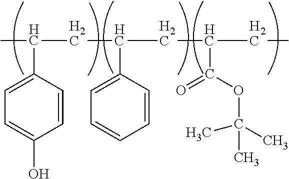

6:2:2 (polymer 1) hydroxystyrene:styrene:t-butyl acrylate copolymer, Toho Chemical Industry, molar ratio 6:2:2, cLogP =2.79, Mw: about 12,000

The above ratio number indicates the ratio of each repeating unit, and the same applies to the following.

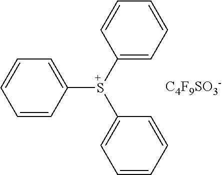

### Photoacid Generator B1

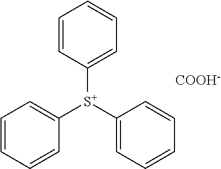

### Photoacid Generator D1

### Preparation of Compositions 2 to 6 and Comparative Compositions 1 and 2

The compounding is changed as shown in Table 1, the solvent is the same as that of Composition 1, the solid content ratio is made to be as shown in Table 1, and the preparation is performed in the same way as that of Composition 1 to obtain Compositions 2 to 6 and Comparative Compositions 1 and 2. In the table, the mass of each component indicates parts by mass.

### Table 1

TABLE 1

| | | | | | | | | Comparative | |
|---|---|---|---|---|---|---|---|---|---|
| | | | | | | | | example | |
| | | | | | | | | Com- | Com- |
| | | Example | | | | | | parative | parative |
| | | Com- | Com- | Com- | Com- | Com- | Com- | com- | com- |
| | | position 1 | position 2 | position 3 | position 4 | position 5 | position 6 | position 1 | position 2 |
| Alkali-soluble | Polymer 1 | 100 | — | — | — | — | — | — | — |
| resin (A) | Polymer 2 | — | 100 | 100 | — | — | — | — | — |
| | Polymer 3 | — | — | — | 100 | — | — | — | — |
| | Polymer 4 | — | — | — | — | 100 | 100 | — | — |
| | Polymer 5 | — | — | — | — | — | — | 100 | — |
| | Polymer 6 | — | — | — | — | — | — | — | 100 |
| Photoacid | Photoacid | 2.85 | — | 2.85 | — | — | 2.85 | 2.85 | 2.85 |
| generator (B) | generator B1 | | | | | | | | |
| | Photoacid | — | 3.70 | — | 3.70 | 3.70 | — | — | — |
| | generator B2 | | | | | | | | |
| Photoacid | Photoacid | 0.07 | — | 0.07 | — | — | 0.07 | 0.07 | 0.07 |
| generator (D) | generator D1 | | | | | | | | |
| | Photoacid | — | 0.7 | — | 0.7 | 0.7 | — | — | — |
| | generator D2 | | | | | | | | |
| Basic | Basic | 0.14 | — | 0.14 | — | — | 0.14 | 0.14 | 0.14 |
| compound (E) | compound 1 | | | | | | | | |
| Surfactant (F) | Surfactant 1 | 0.06 | 0.06 | 0.06 | 0.06 | 0.06 | 0.06 | 0.06 | 0.06 |
| Additive (G) | Surface | 4 | 8 | 4 | 8 | 8 | 4 | 4 | 4 |
| | smoothing | | | | | | | | |
| | agent 1 | | | | | | | | |

| | | | | | | | | |
|---|---|---|---|---|---|---|---|---|
| Solid content ratio (mass %) | 10.71 | 7.31 | 10.71 | 7.31 | 7.31 | 10.71 | 10.71 | 10.71 |
| Tr/T (%) | 13 | 8 | 10 | 11 | 6 | 7 | 39 | 49 |

In the table,
polymer 1: 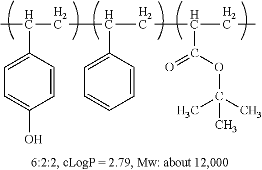
polymer 2: 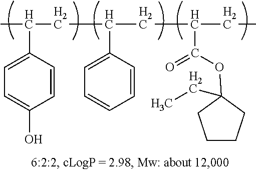
polymer 3: 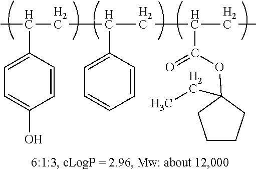
polymer 4: 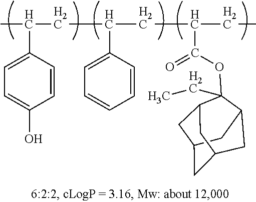
polymer 5: 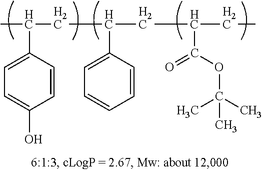
polymer 6: 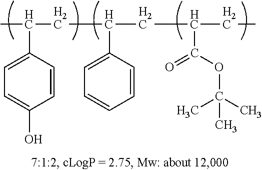
photoacid generator B1: 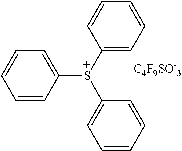
photoacid generator B2: 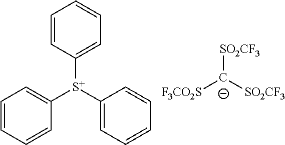
photoacid generator D1: 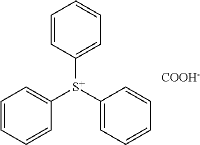
photoacid generator D2: 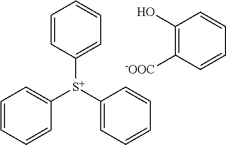
basic compound 1: triethanolamine
surfactant 1: Megafac R-2011, DIC
surface smoothing agent 1: N,N-dimethylacrylamide

### Evaluation of Polymer Film Loss Amount

A solution prepared by adding each polymer 1 to 5 in PGME to become 8 mass % is applied onto a substrate using a coater Mark 8 (Tokyo Electron), and baking is performed at 110° C. for 60 seconds. The film thickness at this time is measured using the spectroscopic film thickness measurement system LambdaAce VN-12010 (SCREEN) (the same applies to the following film thickness measurement). As for the film thickness, it is measured at eight points on the wafer excluding the central portion, and the average value thereof is used. Then, the substrate is immersed in a 2.38 mass % TMAH aqueous solution used as a for 60 seconds, washed and dried, and thereafter, the film thickness is measured again. The results obtained are as shown in Table 2.

TABLE 2

| | | Film thickness | Film thickness | Film loss |
|---|---|---|---|---|
| | | before development | after development | amount |
| | cLogP | (nm) | (nm) | (nm) |
| Polymer 1 | 2.79 | 347.2 | 307.8 | 39.4 |
| Polymer 2 | 2.98 | 324.0 | 322.0 | 2.0 |
| Polymer 3 | 2.96 | 251.9 | 245.6 | 6.3 |
| Polymer 4 | 3.06 | 295.7 | 295.7 | 0.0 |
| Polymer 5 | 2.67 | 355.5 | 272.2 | 83.3 |
| Polymer 6 | 2.75 | — | — | — |

### Evaluation of Resist Pattern Formation

A bottom anti-reflective coating layer forming composition AZ KrF-17B (Merck Performance Materials (hereinafter referred to as MPM)) is applied onto an 8-inch silicon wafer, and baking is performed at 180° C. for 60 seconds to form a bottom anti-reflective coating layer having a thickness of 80 nm. On it, the above each composition is dropped and coated by spinning. This wafer is baked on a hot plate at 110° C. for 60 seconds to form a resist film. The film thickness at this time is 400 nm, respectively. The resist film is exposed using a KrF stepper (FPA 300-EX5, CANON). A mask pattern of Dense Line, L:S 1:1 and 180 nm is used. Then, the wafer is baked (PEB) on a hot plate at 140° C. for 60 seconds. This is subjected to paddle development with a 2.38 mass % TMAH aqueous solution for 60 seconds. As a result, a resist pattern having Line=1700 nm and Space (trench)=340 nm (Line:Space=5:1) is obtained. The cross-sectional shape of the resist pattern is confirmed using CD-SEM S9200 (Hitachi High-Tech), and the above-described Tr/T is calculated. The results obtained are as shown in Table 1.

As described above, it is confirmed that the resist composition of the present invention can form a good rectangular resist pattern, and that film loss of the polymer used in the resist composition is small.

### EXPLANATION OF SYMBOLS

1. substrate
2. resist pattern
3. resist top
4. resist bottom

1.-15. (canceled)

16. A chemically amplified resist composition comprising an alkali-soluble resin (A), a photoacid generator (B) and a solvent (C),
wherein
cLogP of the alkali-soluble resin (A) is 2.76 to 3.35, and the alkali-soluble resin (A) comprises at least one of the following repeating units: 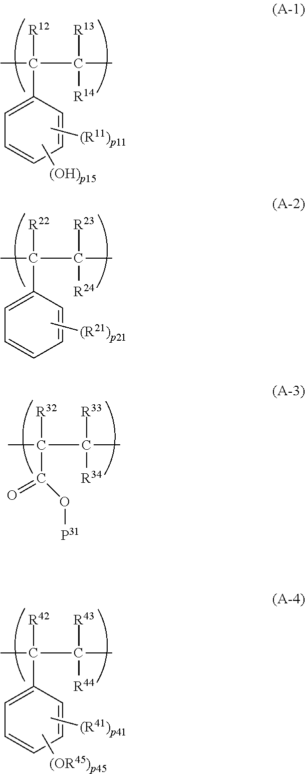
where
R¹¹, R²¹, R⁴¹ and R⁴⁵ are each independently C₁₋₅ alkyl (where —CH₂— in the alkyl can be replaced with —O—);
R¹², R¹³, R¹⁴, R²², R²³, R²⁴, R³², R³³, R³⁴, R⁴², R⁴³ and R⁴⁴ are each independently C₁₋₅ alkyl, C₁₋₅ alkoxy or —COOH;
p111 is 0 to 4, p15 is 1 to 2, and p11+p15≤<5;
p21 is 0 to 5;
p41 is 0 to 4, p45 is 1 to 2, and p41+p45≤5;
P³¹ is C₄₋₂₀ alkyl, where a part or all of the alkyl can form a ring, and a part or all of H in the alkyl can be replaced with halogen.

17. The chemically amplified resist composition according to claim 16, wherein the photoacid generator (B) is represented by the formula (B-1) or the formula (B-2):
Bⁿ⁺cation Bⁿ⁻anion (B-1)
wherein
the Bⁿ⁺cation is a cation represented by the formula (BC1), a cation represented by the formula (BC2) or a cation represented by the formula (BC3), the Bⁿ⁺cation is n valent as a whole, and n is 1 to 3, and
the Bⁿ⁻anion is an anion represented by the formula (BA1), an anion represented by the formula (BA2), an anion represented by the formula (BA3) or an anion represented by the formula (BA4), and the Bⁿ⁻anion is n valent as a whole: 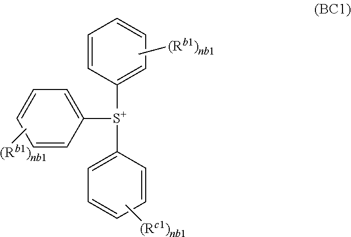
where
R^{b1} is each independently C₁₋₆ alkyl, C₁₋₆ alkoxy, C₆₋₁₂ aryl, C₆₋₁₂ arylthio or C₆₋₁₂ aryloxy, and
nb1 is each independently 0, 1, 2 or 3; 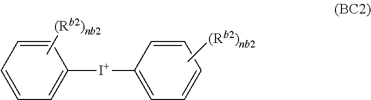
where
R^{b2} is each independently C₁₋₆ alkyl, C₁₋₆ alkoxy or C₆₋₁₂ aryl, and
nb2 is each independently 0, 1, 2 or 3; 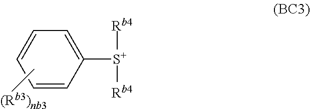
where
R^{b3} is each independently C₁₋₆ alkyl, C₁₋₆ alkoxy or C₆₋₁₂ aryl,
R^{b4} is each independently C₁₋₆ alkyl, and
nb3 is each independently 0, 1, 2 or 3; 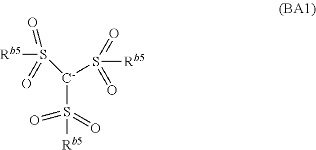
where
R^{b5} is each independently fluorine-substituted C₁₋₆ alkyl, fluorine-substituted C₁₋₆ alkoxy, or C₁₋₆ alkyl;
R^{b6}—SO₃⁻ (BA2)
where
R^{b6} is fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl; 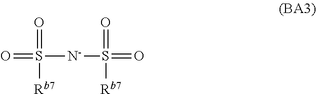
where
R^{b7} is each independently fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl, where two R^{b7} can be bonded to each other to form a fluorine-substituted heterocyclic structure; 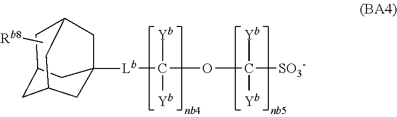
where
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21; 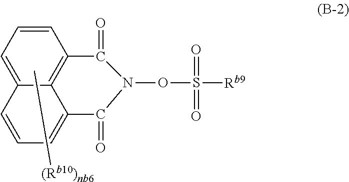
where
R^{b9} is fluorine-substituted C₁₋₅ alkyl,
R^{b10} is each independently C₃₋₁₀ alkenyl or alkynyl (where CH₃— in the alkenyl and alkynyl can be replaced with phenyl, and —CH₂— in the alkenyl and alkynyl can be replaced with at least one of —C(═O)—, —O— or phenylene), C₂₋₁₀ thioalkyl, C₅₋₁₀ saturated heterocycle, and
nb6 is 0, 1 or 2.

18. The chemically amplified resist composition according to claim 16, further comprising a photoacid generator (D), wherein the photoacid generator (D) is represented by the formula (D-1):
D^{m+}cation D^{m-}anion (D-1)
where
the D^{m+}cation is a cation represented by the formula (DC1) or a cation represented by the formula (DC2), and the D^{m+}cation is m valent as a whole,
m is 1 to 3, and
the D^{m-}anion is an anion represented by the formula (DA1) or an anion represented by the formula (DA2), and the D^{m-}anion is m valent as a whole: 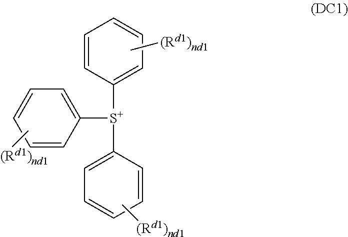
where,
R^{d1} is each independently C₁₋₆ alkyl, C₁₋₆ alkoxy or C₆₋₁₂ aryl, and
nd1 is each independently 0, 1, 2 or 3; 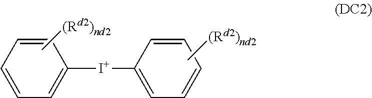
where
R^{d2} is each independently C₁₋₆ alkyl, C₁₋₆ alkoxy or C₆₋₁₂ aryl, and
nd2 is each independently 0, 1, 2 or 3; 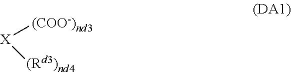
where
X is C₁₋₂₀ hydrocarbon or a single bond,
R^{d3} is each independently hydrogen, hydroxy, C₁₋₆ alkyl, or C₆₋₁₀ aryl,
nd3 is 1, 2 or 3, and
nd4 is 0, 1 or 2;
R^{d4}—SO₃⁻ (DA2)
where
R^{d4} is C₁₋₁₅ alkyl (where a part or all of the alkyl can form a ring and —CH₂— in the alkyl can be replaced with —C(═O)—).

19. The chemically amplified resist composition according to claim 16, further comprising a basic compound (E):
preferably, the basic compound (E) is ammonia, C₁₋₁₆ primary aliphatic amine compound, C₂₋₃₂ secondary aliphatic amine compound, C₃₋₄₈ tertiary aliphatic amine compound, C₆₋₃₀ aromatic amine compound or C₅₋₃₀ heterocyclic amine compound.

20. The chemically amplified resist composition according to claim 16, further comprising a surfactant (F):
preferably, the chemically amplified resist composition further comprises an additive (G), which is at least one selected from the group consisting of a surface smoothing agent, a plasticizer, a dye, a contrast enhancer, an acid, a radical generator, a substrate adhesion enhancer and an antifoaming agent.

21. The chemically amplified resist composition according to claim 16, wherein the number of the repeating units n_{A-1}, n_{A-2}, n_{A-3} and n_{A-4} of the repeating units (A-1), (A-2), (A-3) and (A-4) in the alkali-soluble resin (A) satisfies the following:
n_{A-1}/(n_{A-1}+n_{A-2}+n_{A-3}+n_{A-4})=40 to 80%,
n_{A-2}/(n_{A-1}+n_{A-2}+n_{A-3}+n_{A-4})=0 to 40%,
n_{A-3}/(n_{A-1}+n_{A-2}+n_{A-3}+n_{A-4})=0 to 40%, and
n_{A-4}/(n_{A-1}+n_{A-2}+n_{A-3}+n_{A-4})=0 to 40%.
preferably, assuming that the total number of all repeating units contained in the alkali-soluble resin (A) is nₜₒₜₐₗ, following is satisfied:
(n_{A-1}+n_{A-2}+n_{A-3}+n_{A-4})/nₜₒₜₐₗ=80 to 100%.

22. The chemically amplified resist composition according to claim 16, wherein the photoacid generator (B) releases an acid having an acid dissociation constant pKa (H₂O) of —20 to 1.4 upon exposure:
preferably, the photoacid generator (D) releases a weak acid having an acid dissociation constant pKa (H₂O) of 1.5 to 8 upon exposure, or
preferably, the base dissociation constant pKb (H₂O) of the basic compound (E) is −12 to 5.

23. The chemically amplified resist composition according to claim 16, wherein the content of the alkali-soluble resin (A) is more than 0 mass % and 20 mass % or less, based on the chemically amplified resist composition,
the content of the photoacid generator (B) is more than 0 mass % and 20 mass % or less, based on the alkali-soluble resin (A), and
the content of the solvent (C) is 80 mass % or more and less than 100 mass %, based on the chemically amplified resist composition:
preferably, the content of the photoacid generator (D) is 0.01 to 5 mass %, based on the alkali-soluble resin (A),
preferably, the content of the basic compound (E) is 0.01 to 3 mass %, based on the alkali-soluble resin (A),
preferably, the content of the surfactant (F) is more than 0 mass % and 1 mass % or less, based on the alkali-soluble resin (A), or
preferably, the alkali-soluble resin (A) has a mass average molecular weight of 1,000 to 50,000.

24. The chemically amplified resist composition according to claim 16, wherein the solvent (C) is water, a hydrocarbon solvent, an ether solvent, an ester solvent, an alcohol solvent, a ketone solvent, or a combination of any of these.

25. The chemically amplified resist composition according to claim 16, which is a thin film chemically amplified resist composition:
preferably, the thin film chemically amplified resist composition is a thin film KrF chemically amplified resist composition;
preferably, the thin film chemically amplified resist composition is a thin film positive type chemically amplified resist composition; or
preferably, the thin film chemically amplified resist composition is a thin film KrF positive type chemically amplified resist composition.

26. A method for manufacturing a resist film comprising the following steps:
(1) applying the composition according to claim 16 above a substrate; and
(2) heating the composition to form a resist film:
preferably, the film thickness of the resist film is 50 nm to 1,000 nm;
preferably, the heating in the step (2) is performed at 100 to 250° C. and/or for 30 to 300 seconds; or
preferably, the heating in the step (2) is performed in an atmosphere or a nitrogen gas atmosphere.

27. A method for manufacturing a resist pattern comprising the following steps:
forming a resist film by the method according to claim 26;
(3) exposing the resist film; and
(4) developing the resist film.

28. The method for manufacturing a resist pattern according to claim 27, wherein assuming that the height from the top to the bottom of the resist pattern is T, the resist width at the height from the bottom of the resist pattern of 0.5 T is W_{0.5}, the height at which resist width is 0.99 W_{0.5} is T′, and the difference between the height T and the height T′ is Tr, Tr/T=0 to 25% is satisfied.

29. A method for manufacturing a processed substrate comprising the following steps:
forming a resist pattern by the method according to claims 27; and
(5) processing using the resist pattern as a mask:
preferably, in the step (5), the underlayer film or the substrate is processed.

30. A method for manufacturing a device comprising the method according to claim 26:
preferably, a step of forming a wiring on the processed substrate is further comprised; or preferably, the device is a semiconductor device.
